(19) United States
(12) Patent Application Publication
(10) Pub. No.: US 2010/0213437 A1
(43) Pub. Date: Aug. 26, 2010

(54) LIGHT EMITTING DEVICE

(75) Inventors: Tomonori Akai, Tokyo-To (JP); Masaya Shimogawara, Tokyo-To (JP)

Correspondence Address: BURR & BROWN, PO BOX 7068, SYRACUSE, NY, 13261-7068, US

(73) Assignee: Dai Nippon Printing Co., Ltd., Shinjuku-ku (JP)

(21) Appl. No.: 12/680,036

(22) PCT Filed: Sep. 29, 2008
(86) PCT No.: PCT/JP2008/067667

§ 371 Date: May 5, 2010

(30) Foreign Application Priority Data
Sep. 28, 2007 (JP) 2007-256371

(51) Int. Cl. H01L 33/04; H01L 23/58

(52) U.S. Cl. 257/13; 257/48; 977/950; 977/774; 257/E33.002; 257/E33.008

(57) ABSTRACT

The present invention provides a light emitting device that comprises a luminescent layer formed of a monomolecular film of quantum dots and has enhanced brightness and luminescence efficiency. A light emitting device 1 comprises at least an anode 3, a hole transport luminescent layer 5 formed of a material containing a hole transport material and quantum dots 11, an electron transport layer 7, and a cathode 4 provided in that order. The light emitting device 1 is constructed so that the hole mobility of the electron transport layer 7 is smaller than that of tris(8-quinolinolato)aluminum complex (Alq3), and, in the hole transport luminescent layer 5, excitons generated in the electron transport layer 7 migrate into the luminescent layer to emit light.

### CROSS-REFERENCE TO RELATED APPLICATIONS

This application is based upon and claims the benefit of priority under Article 4 of the Paris Convention from the prior Japanese Patent Applications No. 256371/2007, filed on Sep. 28, 2007, the entire contents of the specifications, drawings, etc. of which are incorporated herein by reference.

### FIELD OF INVENTION

The present invention relates to a light emitting device and more specifically relates to a light emitting device comprising an EL luminescent layer containing quantum dots.

### BACKGROUND ART

An organic electroluminescence device (hereinafter referred to also as organic EL device) is a light emitting device having a laminate structure comprising an organic luminescent layer held between an anode and a cathode and is a self-luminous device utilizing luminescence attributable to recombination, within the luminescent layer, between holes injected from the anode and electrons injected from the cathode. The task of the organic EL device is to realize the prolongation of the service life and improvement in luminescence efficiency of the luminescent material constituting the organic luminescent layer, and studies are currently energetically made to attain the task.

On the other hand, a light emitting device has been proposed that utilizes, as an EL luminescent material, a semiconductor fine particles (called “quantum dots”) that can regulate luminescent color by varying the particle diameter (see, for example, document: Seth Coe et. al., Nature, 420, 800-803 (2002)). The document describes a typical example of quantum dots having a core-shell structure comprising a core of CdSe, a shell of ZnS provided on the outer periphery of the core, and a capping compound provided on the outer periphery of the shell. The light emitting device using the quantum dots as a luminescent material is advantageous in that the width of a luminescence spectrum is smaller than that in a light emitting device using the organic EL material and, thus, the color purity can be enhanced.

As shown in FIG. 1 in the document, the light emitting device is disadvantageous in that, since the luminescent layer provided in the light emitting device proposed in the document is formed of a monomolecular film of quantum dots, excitons generated by recombination of charges injected from both the electrodes have less opportunity to reach the monomolecular film and to be consumed in EL luminescence and, consequently, satisfactory brightness and luminescence efficiency cannot be realized. This document also proposes, as an example, increasing the probability of recombination within the luminescent layer by providing a hole block layer between the luminescent layer and the electron transport layer. However, satisfactorily high brightness and luminescence efficiency are not realized.

Japanese Translation of PCT Publication No. 502176/2005 and Japanese Translation of PCT Publication No. 513478/2007 propose an example of a light emitting device comprising a luminescent layer that comprises quantum dots dispersed in a host material to enhance the probability of recombination of charges within the luminescent layer. The claimed advantage of this light emitting device is that the produced excitons migrate within the luminescent layer to cause EL luminescence of the quantum dots.

### SUMMARY OF THE INVENTION

The present invention has been made with a view to solving the problem of non-patent document 1 that satisfactory brightness and luminescence efficiency cannot be realized, and an object of the present invention is to provide a light emitting device that comprises a luminescent layer using quantum dots as an EL luminescent material and has enhanced brightness and luminescence efficiency.

The above object can be attained by a light emitting device comprising at least an anode, a hole transport luminescent layer formed of a material containing a hole transport material and quantum dots, an electron transport layer, and a cathode provided in that order, characterized in that the hole mobility of the electron transport layer is smaller than that of tris(8-quinolinolato)aluminum complex (Alq3), and in the hole transport luminescent layer, excitons generated in the electron transport layer migrate into the luminescent layer to emit light.

According to the present invention, since the hole mobility of the electron transport layer is smaller than that of tris(8-quinolinolato)aluminum complex (Alq3), a part of holes injected from the anode into the hole transport luminescent layer is recombined with electrons within the hole transport luminescent layer while the other holes are passed through the hole transport luminescent layer and are recombined with electrons within the electron transport layer at its portion close to the hole transport luminescent layer. As a result, excitons produced by recombination within the electron transport layer easily migrate into the hole transport luminescent layer and are consumed in EL luminescence of quantum dots, and, thus, a recombination area which substantially contributes to the luminescence of quantum dots is increased, leading to an enhanced luminescence efficiency.

In a preferred embodiment of the light emitting device according to the present invention, the light emitting device is constructed to meet [Ip(ETL)]<[Ip(HTL)+1.0 eV] wherein Ip(ETL) represents the absolute value of the ionization potential of an electron transport material that forms the electron transport layer; and Ip(HTL) represents the absolute value of the ionization potential of the hole transport material.

In a preferred embodiment of the light emitting device according to the present invention, the electron transport layer has a hole mobility of not more than 10⁻⁷ cm²/V/sec.

In a preferred embodiment of the light emitting device according to the present invention, the hole mobility is measured by providing a test piece formed of ITO (150 nm)/PEDOT (20 nm)/αNPD (20 nm)/measuring object (100 nm)/Au (100 nm), applying 10 V to the test piece, and, in this state, measuring a current value in a hole-only device.

In a preferred embodiment of the light emitting device according to the present invention, the electron transport layer has a thickness of not less than 30 nm and not more than 150 nm.

In a preferred embodiment of the light emitting device according to the present invention, the electron transport layer comprises BAlq2 as an electron transport material.

In a preferred embodiment of the light emitting device according to the present invention, a dopant that enhances a recombination probability at sites on the hole transport luminescent layer side is contained at least at sites on the hole transport luminescent layer side of the electron transport layer.

In a preferred embodiment of the light emitting device according to the present invention, the hole transport luminescent layer is any one of a layer comprising the hole transport material and the quantum dots dispersed in each other, a layer comprising a hole transport layer formed by phase separation between the hole transport material and the quantum dots and a monomolecular film of quantum dots, and a layer in a state intermediate between the layers.

According to the light emitting device of the present invention, a part of holes injected from the anode into the hole transport luminescent layer is recombined with electrons within the hole transport luminescent layer, and other holes which could not have contributed to the recombination are passed through the hole transport luminescent layer and are recombined with electrons within the electron transport layer at its portion close to the hole transport luminescent layer. Thus, all the holes contribute to luminescence of the quantum dots. As a result, excitons produced by recombination within the electron transport layer easily migrate into the hole transport luminescent layer and are consumed in EL luminescence of quantum dots, and, thus, a recombination area which substantially contributes to the luminescence of quantum dots is increased, leading to an enhanced luminescence efficiency.

### BRIEF DESCRIPTION OF THE DRAWINGS

FIG. 1 is a typical cross-sectional view showing one embodiment of a light emitting device according to the present invention.

FIG. 2 is a typical cross-sectional view showing one embodiment of a light emitting device according to the present invention.

FIG. 3 is a typical diagram for explaining the principle of luminescence of a light emitting device according to the present invention.

FIG. 4 is an energy diagram showing an ionization potential of materials constituting respective layers used in working examples.

### DESCRIPTION OF REFERENCE CHARACTERS

1 Light emitting device
2 Base material
3 Anode
4 Cathode
5 Luminescent layer
5A Single layer
5B Monomolecular film of quantum dots
6 Hole transport layer
7 Electron transport layer
7A Recombination area
11 Quantum dots
12 Excitons

### DETAILED DESCRIPTION OF THE INVENTION

Embodiments of the light emitting device according to the present invention will be described. The present invention, however, is not to be construed as being limited to the following embodiments and the accompanying drawings.

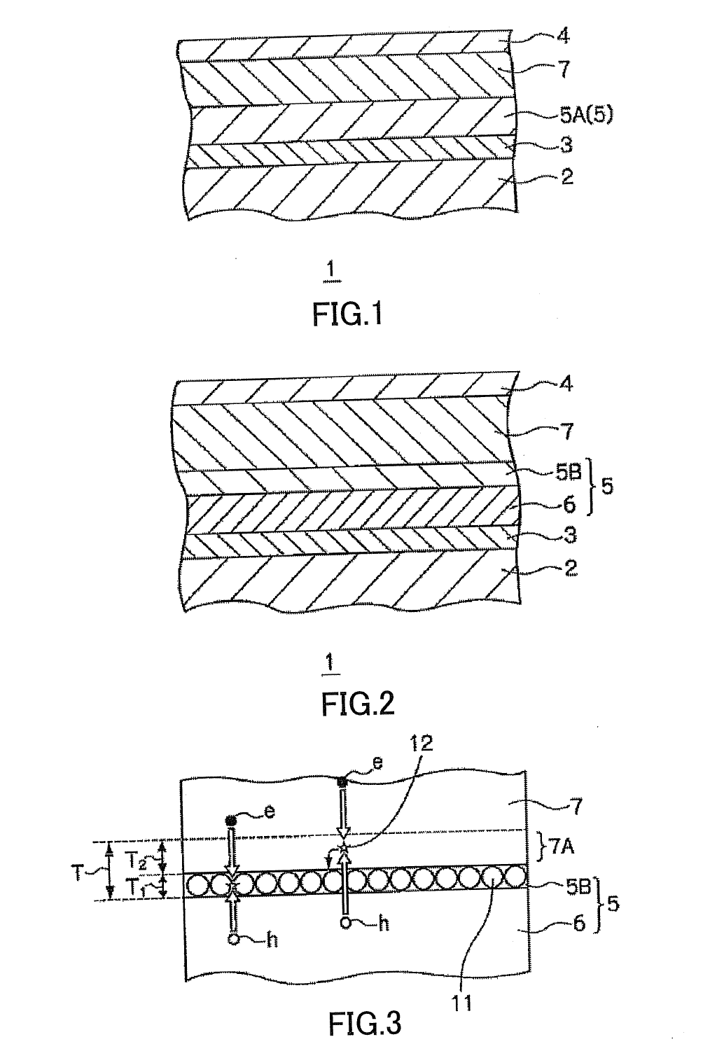

FIG. 1 is a typical cross-sectional view showing one embodiment of a light emitting device according to the present invention, FIG. 2 a typical cross-sectional view showing another one embodiment of a light emitting device according to the present invention, and FIG. 3 a typical diagram for explaining the principle of luminescence of a light emitting device according to the present invention. As shown in FIGS. 1 and 2, a light emitting device 1 according to the present invention comprises at least an anode 3, a hole transport luminescent layer 5 formed of a material containing a hole transport material and quantum dots, an electron transport layer 7, and a cathode 4 provided in that order. The light emitting device 1 is constructed so that the hole mobility of the electron transport layer 7 is smaller than that of tris(8-quinolinolato)aluminum complex (Alq3), and, in the hole transport luminescent layer 5, excitons generated in the electron transport layer 7 migrate into the hole transport luminescent layer 5 to emit light.

The “hole transport luminescent layer 5” referred to herein is defined as including a single layer 5A, as shown in FIG. 1, comprising a hole transport material and quantum dots dispersed in each other, and a composite layer, as shown in FIG. 2, that has been formed by phase separation between the hole transport material and the quantum dots and comprises a hole transport layer 6 and a monomolecular film 5B of quantum dots, and is further defined as including a layer in a state intermediate between the single layer 5A and the composite layer, that is, a layer that is not in a completely phase separated state but cannot be said to be a single layer. In the following description, the hole transport luminescent layer 5 will be simply abbreviated as “luminescent layer 5.”

Next, the constituent elements of the light emitting device according to the present invention will be described in more detail. The present invention, however, is not to be construed to the following embodiments only. In the following description, when the expression “upper” and “lower” are used, the upper side and the lower side in a planar view of FIG. 1 mean “upper” and “lower,” respectively.

(Base Material)

In the embodiment shown in FIG. 1, a base material 2 is provided as a base material for an anode 3. However, the present invention is not particularly limited to this embodiment, and the base material 2 may be provided on the upper side of a cathode 4 or may be provided as the base material for the anode 3 and, at the same time, on the upper side of the cathode 4. The transparency of the base material 2 may be properly selected according to a light outgoing direction, and, when a bottom emission-type light emitting device is contemplated, the base material 2 shown in FIG. 1 should be transparent. The type of the base material and the structure of the base material, i.e., shape, size and thickness, are not particularly limited and may be properly determined, for example, according to the application of the light emitting device 1 and the material of each layer stacked on the base material. Base materials formed of various material, for example, metals such as Al, glass, quartz, or resins may be used. Specific examples thereof include glass, quartz, polyethylene, polypropylene, polyethylene terephthalate, polyethylene naphthalate, polymethacrylate, polymethylmethacrylate, polymethylacrylate, polyester, and polycarbonate. The base material 2 may be in a sheet form or a continuous form, and specific examples thereof include cards, films, disks, and chips.

(Electrode)

The anode 3 and the cathode 4 are electrodes that inject holes and electrodes for emitting light from the quantum dots which are an EL luminescent material. In general, as shown in FIG. 1, the anode 3 is provided on the base material 2, and the cathode 4 is provided so as to face the anode 3 so that at least the luminescent layer 5 and the electron transport layer 7 are held between the cathode 4 and the anode 3.

A thin film formed of, for example, a metal, an electroconductive oxide, or an electroconductive polymer is used as the anode 3. Specific examples thereof include transparent electroconductive films such as ITO (indium tin oxide), indium oxide, IZO (indium zinc oxide), SnO₂, and ZnO, large-work function metals having good hole injectability such as gold and chromium, and electroconductive polymers such as polyaniline, polyacetylene, polyalkylthiophene derivatives, and polysilane derivatives. The anode 3 can be formed by vacuum processes such as vacuum deposition, sputtering, and CVD or coating. The thickness of the anode 3 may vary depending, for example, upon the material used, but is preferably, for example, approximately 10 nm to 1000 nm.

A thin film formed of, for example, a metal, an electroconductive oxide, an electroconductive polymer is used as the cathode 4. Specific examples thereof include small-work function metals having good electron injectability, for example, single metals such as aluminum and silver, magnesium alloys such as MgAg, aluminum alloys such as AlLi, AlCa, and AlMg, alkali metals including Li and Ca, and alloys of the alkali metals. As with the anode 3, the cathode 4 can be formed by vacuum processes such as vacuum deposition, sputtering, and CVD or coating. The thickness of the cathode 4 may vary depending, for example, upon the material used, but is preferably, for example, approximately 10 nm to 1000 nm.

(Luminescent Layer)

The luminescent layer 5 is held between the anode 3 and the cathode 4. Holes injected from the anode 3 are recombined with electrons injected from the cathode 4, and excitons generated by the recombination cause emission of light from quantum dots 11 which are an EL material constituting the luminescent layer 5. As described above, the luminescent layer 5 may be any of a single layer 5A, as shown in FIG. 1, comprising a hole transport material and quantum dots dispersed in each other, a composite layer, as shown in FIG. 2, that has been formed by phase separation between the hole transport material and the quantum dots and comprises a hole transport layer 6 and a monomolecular film 5B of quantum dots, and a layer in a state intermediate between the single layer 5A and the composite layer, that is, a layer that is not in a completely phase separated state but cannot be said to be a single layer.

The quantum dots 11 constituting the luminescent layer 5 are semiconductor fine particles that can regulate luminescent color by varying the particle diameter. The quantum dots 11 are called nanoparticles and nanocrystals, and a typical example thereof comprises a core of CdSe, a ZnS shell provided on the outer periphery of the core, and a capping compound provided on the outer periphery of the shell. When the particle diameter of the quantum dots 11 is varied, light having a different color is emitted. For example, when the quantum dots consist of a core of CdSe only, the peak wavelengths of fluorescence spectra for particle diameters of 2.3 nm, 3.0 nm, 3.8 nm, and 4.6 nm are 528 nm, 570 nm, 592 nm, and 637 nm, respectively.

The quantum dots 11 are not particularly limited as long as they are semiconductor fine particles (semiconductor nanocrystals) of nanometer size and are a luminescent material that exhibits a quantum confinement effect (quantum size effect). Specific examples of such luminescent materials include group II-VI semiconductor compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe, group III-V semiconductor compounds such as AlN, AlP, AlAs, AlSb, GaAs, GaP, GaN, GaSb, InN, InAs, InP, InSb, TiN, TiP, TiAs, and TiSb, semiconductor crystals containing group IV semiconductors such as Si, Ge, and Pb, and, further, semiconductor compounds containing three or more elements such as InGaP. Alternatively, semiconductor crystals comprising the semiconductor compound doped with a cation of a rare earth metal or a cation of a transition metal, for example, Eu³⁺, Tb³⁺, Ag⁺, or Cu⁺, may also be used.

Among others, semiconductor crystals such as CdS, CdSe, CdTe, or InGaP are suitable from the viewpoints of easiness of preparation, the controllability of the particle diameter which provides luminescence in a visible range, and fluorescence quantum yield.

The quantum dots 11 may be formed of one semiconductor compound or two or more semiconductor compounds. For example, the quantum dots 11 may have a core-shell structure comprising a core formed of a semiconductor compound and a shell formed of a semiconductor compound different from the compound constituting the core. The luminescence efficiency of the core-shell-type quantum dots can be enhanced by using, as a semiconductor compound constituting the shell, a material that has a higher band gap than the semiconductor compound constituting the core so that excitons are confined in the core. Examples of the core-shell structure (core/shell) having a magnitude relation in the band gap between the core and the shell include CdSe/ZnS, CdSe/ZnSe, CdSe/CdS, CdTe/CdS, InP/ZnS, GaP/ZnS, Si/ZnS, InN/GaN, InP/CdSSe, InP/ZnSeTe, GaInP/ZnSe, GaInP/ZnS, Si/AlP, InP/ZnSTe, GaInP/ZnSTe, and GaInP/ZnSSe.

The size of the quantum dots 11 may be properly regulated depending upon the material for constituting the quantum dots to obtain light having a desired wavelength. The energy band gap of the quantum dots increases with reducing the particle diameter of the quantum dots. That is, as the crystal size decreases, the luminescence of the quantum dots shifts toward blue, that is, higher energy. Accordingly, the luminescence wavelength can be regulated over wavelength ranges of an ultraviolet range spectrum, a visible range spectrum, and an infrared range spectrum by varying the size of quantum dots.

In general, the particle diameter of the quantum dots 11 is preferably in the range of 0.5 to 20 nm, particularly preferably in the range of 1 to 10 nm. When the size distribution of the quantum dots is narrower, a luminescent color having higher sharpness can be provided.

The shape of the quantum dots 11 is not particularly limited, and the quantum dots 11 may be in a spherical, rod, disk, or other form. When the quantum dots are not spherical, the particle diameter of the quantum dots may be assumed to be the particle diameter of spheres having the same volume as the non-spherical quantum dots.

Information about the particle diameter, shape, dispersed state and the like of the quantum dots 11 can be obtained with a transmission electron microscope (TEM). Further, the crystal structure and particle diameter of the quantum dots can be learned from X-ray crystal diffraction (XRD). Furthermore, the particle diameter of the quantum dots and information about the surface of the quantum dots can also be obtained by a UV-Vis absorption spectrum.

A quantum dot having a CdSe/ZnS-type core-shall structure basically comprising a core of CdSe, a ZnS shell provided on the outer periphery of the core, and a capping compound provided on the outer periphery of the ZnS shell may be mentioned as a preferred example of the quantum dots 11. When the core-shell structure comprises a core formed of a semiconductor compound and a shell of a semiconductor compound that is different from the compound constituting the core and has a higher band gap than the semiconductor compound constituting the core, excitons are confined in the core. The capping compound functions as a dispersing agent. Specific examples of such capping compounds include, for example, TOPO (tri-n-octylphosphine oxide), TOP (trioctylphosphine), and TBP (tributylphosphine). The above material can realize the dispersion of the quantum dots in an organic solvent.

When the luminescent layer 5 is a single layer 5A shown in FIG. 1 or a monomolecular film 5B of quantum dots shown in FIG. 2, the luminescent layer 5 is generally formed of a single type of quantum dots 11. Alternatively, two or more types of quantum dots which emit predetermined but mutually different luminescent colors may be simultaneously used in the luminescent layer 5. When a monomolecular film 5B of quantum dots as shown in FIG. 2 is formed, a laminate of a plurality of monomolecular films may also be adopted in which a monomolecular film of quantum dots which emit light having a predetermined luminescence color is formed, and a monomolecular film of quantum dots which emit light having another luminescence color is formed thereon.

The luminescent layer 5 can be formed by any method without particular limitation. For example, the single layer 5A shown in FIG. 1 can be formed by preparing a mixed solution composed of the hole transport material to be served as a host material and the quantum dots 11 and coating the mixed solution. On the other hand, when the composite layer, shown in FIG. 2, comprising the monomolecular film 5B of quantum dots and the hole transport layer 6 is formed, the monomolecular film 5B can be formed simultaneously with the formation of the hole transport layer 6. Specifically, for example, a process may be used which comprises preparing a mixed solution composed of TPD (N,N′-bis-(3-methylphenyl)-N,N′-bis-(phenyl)-benzidine) and quantum dots and coating the mixed solution to form a hole transport layer 6 and to form a monomolecular film 5B of quantum dots 11 which underwent phase separation from the hole transport layer 6. In this case, the phase separation occurs due to incompatibility between a phenyl group in TPD and an alkyl group in the capping compound constituting the quantum dots 11. Based on this principle, the selection of a group in the material for hole transport layer formation and a capping compound constituting the quantum dots can realize simultaneous formation of the hole transport layer 6 and the monomolecular film 5B of quantum dots by phase separation. Simultaneous formation of the monomolecular film 5B of quantum dots and the hole transport layer 6 by phase separation is highly effective in forming the luminescent layer.

For example, when the luminescent layer 5 is a single layer 5A, shown in FIG. 1, comprising the hole transport material and the quantum dots 11, the thickness of the luminescent layer 5 is generally 10 nm to 200 nm. On the other hand, in the luminescent layer 5, when the monomolecular film 5B of quantum dots shown in FIG. 2 is formed, the thickness of the monomolecular film 5B is preferably substantially the same as the particle diameter of the quantum dots 11 used and is generally not less than 1 nm and not more than 10 nm.

(Hole Transport Material and Hole Transport Layer)

The hole transport material that constitutes the luminescent layer 5 in the embodiment shown in FIG. 1 and is the material constituting the hole transport layer 6 in the embodiment shown in FIG. 2 will be described. In the luminescent layer 5 shown in FIG. 1, the hole transport material contributes to the transport of quantum dots 11 in which holes injected from the anode 3 are dispersed, and, as shown in FIG. 1, is provided on the anode 3 optionally through a hole injection layer. On the other hand, in the hole transport layer 6 shown in FIG. 2, the hole transport material functions to transport holes injected from the anode 3 toward the monomolecular film 5B of quantum dots and is provided on the anode 3 optionally through a hole injection layer.

The hole transport material may be a low-molecular weight material or a high-molecular weight material. Examples of such hole transport materials include arylamine derivatives, anthracene derivatives, carbazole derivatives, thiophene derivatives, fluorene derivatives, distyrylbenzene derivatives, and spiro compounds. When the hole transport layer 6 and the monomolecular film 5B are simultaneously formed by the phase separation, the use of N,N′-bis-(3-methylphenyl)-N,N′-bis-(phenyl)-benzidine (TPD) is preferred. The hole transport material is not limited thereto. Specific examples of arylamine derivatives include bis(N-(1-naphthyl-N-phenyl)-benzidine (α-NPD) and copoly[3,3′-hydroxy-tetraphenylbenzidine/diethylene glycol]carbonate (PC-TPD-DEG). Specific examples of carbazoles include polyvinylcarbazole (PVK). Specific examples of thiophene derivatives include poly[(9,9-dioctylfluorenyl-2,7-diyl)-co-(bithiophene)]. Specific examples of fluorene derivatives include poly[(9,9-dioctylfluorenyl-2,7-diyl)-co-(4,4′-(N-(4-sec-butylphenyl))diphenylamine)] (TFB). Specific examples of spiro compounds include poly[(9,9-dioctylfluorenyl-2,7-diyl)-alt-co-(9,9′-spiro-bifluorene-2,7-diyl)]. These materials may be used either solely or in a combination of two or more.

When the hole transport layer 6 is formed in the embodiment shown in FIG. 2, the hole transport layer 6 can be formed by various methods. The thickness of the hole transport layer may vary depending, for example, upon the material used, but is preferably, for example, approximately 1 nm to 200 nm.

(Electron Transport Layer)

The electron transport layer 7 is provided between the luminescent layer 5 and the cathode 4 and generally functions to transport electrons injected from the cathode 4 toward the luminescent layer 5. In the present invention, as shown in FIG. 3, electrons e injected from the cathode 4 within are recombined with holes h injected from the anode 3 within the electron transport layer 7. Recombination in the electron transport layer 7 at its portion close to the luminescent layer 5 is particularly preferred.

The reason for this will be described with reference to the embodiment shown in FIG. 2. Specifically, in a luminescent layer 5 comprising a monomolecular film 5B of quantum dots, as shown in FIG. 3, the monomolecular film 5B of the quantum dots 11 function as a luminescent site. Accordingly, the thickness T1 of the monomolecular film 5B is very thin and is generally equal to the particle diameter of the quantum dots 11, i.e., approximately 2 nm to 6 nm, and is up to approximately 10 nm. Accordingly, holes h injected from the anode 3 is likely to go through the thin monomolecular film 5B, and, thus, the probability of recombination between the holes h and the electrons e injected from the cathode 4 within the thin monomolecular film 5B is low. Therefore, in non-patent document 1, a hole block layer is provided between the monomolecular film and the electron transport layer. In the present invention, unlike the method disclosed in non-patent document 1, as shown in FIG. 3, the holes h are recombined with the electrons e within the electron transport layer 7 at its portion close to the monomolecular film 5B, and excitons generated by the recombination migrate into the monomolecular film 5B located close to the electron transport layer 7, whereby efficient EL luminescence of the quantum dots 11 constituting the monomolecular film 5B can be realized.

This is true of the single layer 5A (luminescent layer 5) formed of the hole transport material and the quantum dots 11 shown in FIG. 1. Specifically, the thickness of the single layer 5A is not smaller than the thickness of the monomolecular film 5B shown in FIG. 2. However, the holes h injected from the anode 3 are likely to go through the single layer 5A, and, thus, the probability of recombination between the holes h and the electrons e injected from the cathode 4 within the single layer 5A is low. In the present invention, the holes h are recombined with the electrons e within the electron transport layer 7 at its portion close to the single layer 5A (luminescent layer 5), and excitons generated by the recombination migrate into the single layer 5A located close to the electron transport layer 7, whereby efficient EL luminescence of the quantum dots 11 dispersed within the single layer 5A can be realized.

For example, as shown in working examples which will be described later, the electron transport layer 7 formed of BAlq2 has a smaller hole mobility than that of the electron transport layer formed of Alq3 having a hole mobility of not more than 10⁻⁷ cm²/V/sec. In the electron transport material used in the electron transport layer, the electron mobility is generally higher than the hole mobility. Accordingly, when the electron transport layer is formed of BAlq2, the difference in mobility between the holes and the electrons is larger than that in the case where the electron transport layer is formed of Alq3. In this case, there is a high possibility that the holes and the electrons are recombined with each other within the electron transport layer at its portion near the interface on the luminescent layer side. Preferably, the recombination occurs at a portion near the interface of the electron transport layer 7 and the luminescent layer 5, and, preferably, excitons generated by the recombination are easily supplied to the quantum dots 11. To this end, while taking into consideration, for example, the thickness and charge mobility of other hole transport layer 6, other electron transport layer and the like, a dopant which delays the hole mobility of the whole or a part of the inside of the electron transport layer 7 and functions as a recombination center may be added so that an area 7A near the luminescent layer 5 becomes a recombination area.

Dopants which cause fluorescent emission or phosphorescent emission may be added. Examples of such dopants include perylene derivatives, coumarin derivatives, rubrene derivatives, quinacridone derivatives, squalium derivatives, porphyrin derivatives, styryl dyes, tetracene derivatives, pyrazoline derivatives, decacyclenes, phenoxazones, quinoxaline derivatives, carbazole derivatives, and fluorene derivatives. Specific examples thereof include 1-tert-butyl-perylene (TBP), coumarin 6, nile red, 1,4-bis(2,2-diphenylvinyl)benzene (DPVBi), and 1,1,4,4-tetraphenyl-1,3-butadiene (TPB). Further, organic metal complexes which has a heavy metal ion such as platinum and iridium at the center thereof and exhibit phosphorescence may be used as phosphorescent dopants. Specific examples thereof include Ir(ppy)₃, (ppy)₂Ir(acac), Ir(BQ)₃, (BQ)₂Ir(acac), Ir(THP)₃, (THP)₂Ir(acac), Ir(BO)₃, (BO)₂(acac), Ir(BT)₃, (BT)₂Ir(acac), Ir(BTP)₃, (BTP)₂Ir(acac), FIr₆, and PtOEP.

Whether or not the hole mobility of the electron transport layer 7 has the above hole mobility can be evaluated by the following measurement which will be described later in detail in the working examples. Specifically, for hole mobility measurement, a test piece formed of ITO (150 nm)/PEDOT (20 nm)/αNPD (20 nm)/measuring object (100 nm)/Au (100 nm) is prepared. The term “measuring object” as used herein is an object material of which the hole mobility is to be measured. The test piece having the above construction is provided, and 10 V is applied across both electrodes of the test piece to measure the current value at that time in the hole-only device. The magnitude of the hole mobility can be evaluated by comparing the results obtained by the measurement, for example, with the results of measurement using Alq3 as the measuring object. The hole mobility is a conventional method that measures the mobility. For example, a time-of-flight method (TOF method) may also be used.

The thickness T2 of the recombination area 7A is preferably, for example, 1 nm to 10 nm. Consequently, for example, as shown in FIG. 3, a preferred position of recombination between the holes h and the electrons e may be brought to the sum of the thickness T1 of the monomolecular film 5B of quantum dots and the thickness of T2 of the recombination area 7A (T1+T2). The thickness can be rendered much larger than the thickness, for example, in the case where the hole block layer described in non-patent document 1 is provided. As a result, efficient EL luminescence of the quantum dots 11 constituting the luminescent layer 5 can be realized, and improved brightness and luminescence efficiency can be realized.

The lower limit of the hole mobility of the electron transport layer 7 is not particularly limited. Likewise, the thickness of the electron transport layer 7 cannot be unconditionally determined but is generally not less than 30 nm and not more than 150 nm, preferably 50 nm to 120 nm, further preferably 70 nm to 100 nm.

Such materials for the formation of the electron transport layer 7 include, for example, metal complexes, oxadiazole derivatives, triazole derivatives, phenanthroline derivatives, silole derivatives, cyclopentadiene derivatives, and silyl compounds. Specific examples thereof include oxadiazole derivatives, for example, (2-(4-biphenylyl)-5-(4-tert-butylphenyl)-1,3,4-oxadiazole) (PBD); phenanthrolines, for example, bathocuproine (BCP) or bathophenanthroline (BPhen); and aluminum complexes, for example, tris(8-quinolinol)aluminum complex (Alq₃) or bis(2-methyl-8-quinolilato)(p-phenylphenolate)aluminum complex (BAlq2). BAlq2 is particularly preferred. The electron transport layer 7 can be formed by either vacuum deposition or coating using a coating liquid containing the above material for the formation of the electron transport layer.

The light emitting device particularly preferably meets [Ip(ETL)]<[Ip(HTL)+1.0 eV] wherein Ip(ETL) represents the absolute value of the ionization potential of an electron transport material that forms the electron transport layer 7; and Ip(HTL) represents the absolute value of the ionization potential of the hole transport material for hole transport layer 6 formation. Since the electron transport layer 7 and the hole transport layer 6 are respectively formed of the electron transport material and the hole transport material having the above relationship, the recombination area 7A can be formed on the luminescent layer side of the electron transport layer 7.

The value of a work function measured with a photoelectron spectrometer AC-1 (manufactured by RIKEN KEIKI Co., Ltd.) was applied to the ionization potential. A layer formed of a material to be measured was formed as a single layer on a cleaned glass substrate (manufactured by Sanyo Vacuum Industries Co., Ltd.) with ITO, and the energy value at which photoelectrons was released was measured with a photoelectron spectrometer AC-1 to determine the ionization potential. The measurement was carried out under conditions of a quantity of light of 50 nW and intervals of 0.05 eV.

(Other Layers)

The electron injection layer (not shown) is optionally provided and functions to facilitate injection of electrons from the cathode 4. Materials for electron injection layer formation include alkali metals, halides of alkali metals, and organic complexes of alkali metals, for example, aluminum, lithium fluoride, strontium, magnesium oxide, magnesium fluoride, strontium fluoride, calcium fluoride, barium fluoride, aluminum oxide, strontium oxide, calcium, sodium polymethylmethacrylate polystyrene sulfonate, lithium, cesium, and cesium fluoride. The electron injection layer can be formed by various methods. The thickness of the electron injection layer may vary depending, for example, upon the material used, but is preferably, for example, approximately 0.1 nm to 30 nm.

The hole injection layer (not shown) is optionally provided and functions to facilitate injection of holes from the anode 3. Materials which have hitherto been known as materials for hole injection layer formation, for example, poly(3,4)ethylenedioxythiophene/polystyrenesulfonate (abbreviated to PEDOT/PSS, manufactured by Bayer Co. Ltd., tradename; Baytron P CH8000, commercially available as an aqueous solution), may be used as the material for hole injection layer formation. The hole injection layer can be formed by various methods. The thickness of the hole injection layer may vary depending, for example, upon the material used, but is preferably, for example, approximately 1 nm to 100 nm.

A passivation layer (not shown) is also optionally provided. The passivation layer is a layer that is provided so as to cover the whole device to prevent the formed luminescent layer 5 and electron transport layer 7 and the like from being deteriorated by water vapor or oxygen. Materials for passivation layer formation include silicon oxide, silicon nitride, and silicon oxynitride. The thickness of the passivation layer may vary depending upon the material for passivation layer formation, and the passivation layer is formed to a thickness large enough to avoid a deterioration by water vapor or oxygen.

The reflective layer (not shown) is also not an indispensable layer. The reflective layer functions to efficiently take out light produced in the luminescent layer 5 into the outside of the device and to enhance luminescence efficiency and thus is preferably provided. The reflective layer may be provided solely as an independent layer, or alternatively may be provided in a resonator structure of a totally reflective layer/semi-transparent reflective layer pair. The reflective layer is generally preferably a transparent electroconductive film or a metal layer such as a gold or chromium layer.

(Energy Diagram)

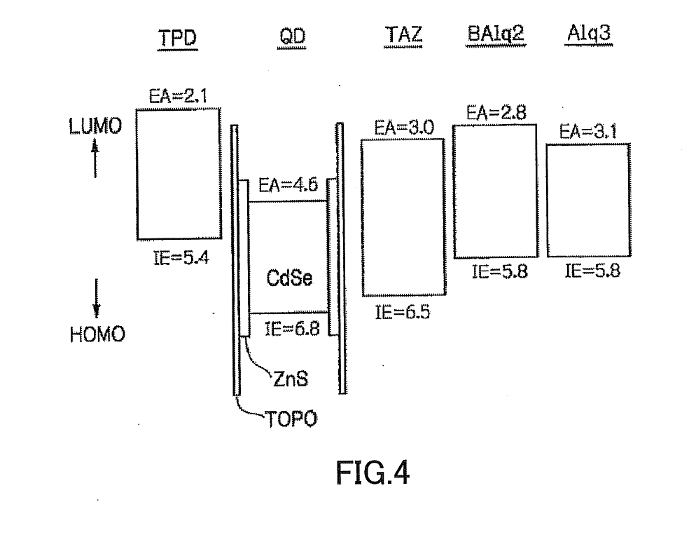

The characteristics of the light emitting device according to the present invention will be described with reference to an energy diagram. FIG. 4 is an energy diagram showing ionization potentials of materials for constituting the layers used in the working examples which will be described later. In the present application, BAlq2 having an HOMO energy value of 5.8 eV was used as the electron transport layer 7. Accordingly, the difference between the energy value (5.4 eV) of TPD constituting the hole transport layer 6 and the energy value of BAlq2 is small and 0.4 eV, and, thus, holes h supplied to the hole transport layer 6 can be relatively easily introduced into the electron transport layer 7 and, as described above, can form a recombination area 7A having a predetermined thickness of T2. On the other hand, for example, as described in non-patent document 1, when TAZ having an HOMO energy value of 6.5 eV is used as the electron transport layer 7, the difference between the energy value (5.4 eV) of TPD constituting the hole transport layer 6 and the energy value of TAZ is large and 1.1 eV. Thus, the electron transport layer 7 of TAZ functions as a hole block layer, is less likely to form the recombination area 7A unlike the present invention, and has less opportunity to cause recombination of charges (holes h, electrons e). Alq3 having the same HOMO energy value (5.8 eV) as BAlq2 is also usable as the material for the electron transport layer 7 formation. However, Alq3 has a relatively high charge mobility and thus cannot be used.

As described above, according to the light emitting device 1 of the present invention, since the hole mobility of the electron transport layer 7 is smaller than that of tris(8-quinolinolato)aluminum complex (Alq3), holes injected from the anode 3 are passed through the luminescent layer 5 and are recombined with electrons injected from the cathode 4 within the electron transport layer 7 at its portion close to the luminescent layer 5. Excitons 12 generated by the recombination easily migrate into the luminescent layer 5 to cause EL luminescence of the quantum dots 11. Accordingly, the brightness and the luminescence efficiency can be improved, and, thus, a high luminescence efficiency can be realized.

### EXAMPLES

The present invention will be described in more detail with reference to the following Examples. The present invention, however, is not to be construed as being limited thereto.

### Example 1

A thin film (thickness: 150 nm) of indium tin oxide (ITO) was first formed by spattering on a glass substrate to form an anode. The substrate with the anode formed thereon was cleaned and was subjected to UV ozone treatment. Thereafter, a solution of polyethylenedioxythiophene-polystyrene sulfonic acid (abbreviated to “PEDOT-PSS”) was then spin coated in the air onto the ITO thin film, and the coating was dried to form a hole injection layer (thickness: 20 nm).

A mixed solution prepared by mixing N,N′-bis-(3-methylphenyl)-N,N′-bis-(phenyl)-benzidine (TPD) and quantum dots (core: CdSe; shell: ZnS; luminescence wavelength: 520 nm; manufactured by Evident Technologies, Inc.) with toluene was spin coated onto the hole injection layer within a glove box in a low-oxygen (oxygen concentration: not more than 0.1 ppm) and low-humidity (water vapor concentration: not more than 0.1 ppm) state to form a hole transport layer and a luminescent layer (total thickness: 40 nm). The hole transport layer and the luminescent layer were formed by converting a luminescent layer formed of quantum dots to a monomolecular film through the phase separation between TPD and the quantum dots. The weight ratio between TPD and the quantum dots in the mixed solution was TPD/quantum dot=9/2.

A film of bis(2-methyl-8-quinolilato)(p-phenylphenolate)aluminum complex (BAlq2) was formed on the substrate on which layers up to the luminescent layer formed thereto in vacuo (pressure: 5×10⁻⁵ Pa) by a resistance heating-type vapor deposition method to form an electron transport layer (thickness: 80 nm). Further, a film of LiF (thickness: 0.5 nm) and a film of Al (thickness: 150 nm) were formed in that order by a resistance heating-type vapor deposition method to form an electron injection layer and a cathode. The assembly was sealed in a glove box in a low-oxygen (oxygen concentration: not more than 0.1 ppm) and low-humidity (water vapor concentration: not more than 0.1 ppm) state with an alkali-free glass to produce a light emitting device.

A voltage was applied across the anode and the cathode in the light emitting device, and the brightness of light emitted in a direction perpendicular to the substrate plane was measured. As a result, light emission derived from the quantum dots was observed. Light emission defects such as dark spots were not observed when the light emitting device was inspected with the naked eye.

### Comparative Example 1

A light emitting device of Comparative Example 1 was produced in the same manner as in Example 1, except that, instead of the electron transport layer formed of BAlq2, a 10-nm thick layer of TAZ (3-(4-biphenyl)-4-phenyl-5-t-butylphenyl-1,2,4-triazole) and a 40 nm-thick electron transport layer of Alq3 were formed in that order in vacuo (pressure: 5×10⁻⁵ Pa) by a resistance heating-type vapor deposition method.

### Comparative Example 2

A light emitting device of Comparative Example 2 was produced in the same manner as in Example 1, except that a 40 nm-thick electron transport layer of Alq3 was formed instead of the electron transport layer of BAlq2.

### Example 2

A light emitting device of Example 2 was produced in the same manner as in Example 1, except that the hole transport layer and the luminescent layer were simultaneously formed by coating, on the hole injection layer, the same mixed solution as in Example 1 except that the mixing ratio of TPD to the quantum dots in the mixed solution was changed to 9:5, and a 60 nm-thick electron transport layer of BAlq2 was formed instead of the electron transport layer of BAlq2 in Example 1.

### Example 3

A light emitting device of Example 3 was produced in the same manner as in Example 2, except that the thickness of the electron transport layer of BAlq2 in Example 2 was changed to 40 nm.

### Example 4

A light emitting device of Example 4 was produced in the same manner as in Example 1, except that the thickness of the electron transport layer of BAlq2 in Example 2 was changed to 20 nm.

(Measurement of Layer Thickness of Light Emitting Devices)

Unless otherwise specified, the thickness of each of the layers according to the present invention was determined by stacking PEDOT-PSS (20 nm) on a cleaned glass substrate with ITO (manufactured by Sanyo Vacuum Industries Co., Ltd.) in the same manner as described above, forming each layer having a single layer structure on the glass substrate, and measuring the thickness of the formed difference in level, provided that the thickness of PEDOT-PSS was excluded. The layer thickness was measured with a probe microscope (Nanopics1000, manufactured by SII NanoTechnology Inc.).

(Current Efficiency and Power Efficiency)

The current efficiency and service lifetime properties of the light emitting devices were evaluated. The current efficiency and the power efficiency were calculated by current-voltage-brightness (I-V-L) measurement. I-V-L measurement was carried out by connecting the cathode to ground and applying a positive direct current voltage to the anode while scanning at 100 mV intervals (1 sec./div.) to record current and brightness at each voltage. The brightness was measured with a luminance meter BM-8 manufactured by TOPCON CORPORATION. Based on the results thus obtained, the luminescence efficiency (cd/A) was calculated from the luminescent area, current, and brightness. The results thus obtained are shown in Tables 1 and 2.

TABLE 1

| | Luminescence efficiency | Maximum luminescence |
|---|---|---|
| | at 100 nit (Cd/A) | Efficiency (Cd/A) |
| Example 1 | 2.9 | 3.6 |
| Comparative | 1.3 | 3.2 |
| Example 1 | | |

*) At 100 nit . . . When the brightness was 100 Cd/m²

TABLE 2

| | Luminescence efficiency | Maximum luminescence |
|---|---|---|
| | at 100 nit (Cd/A) | Efficiency (Cd/A) |
| Example 2 | 4.2 | 16.1 |
| Reference | 2.8 | 9.2 |
| Example 1 | | |
| Reference | 0.3 | 0.6 |
| Example 2 | | |

*) At 100 nit . . . When the brightness is 100 Cd/m²

In the light emitting device of Comparative Example 2, the luminescence intensity of Alq3 was higher than that of the quantum dots. The reason for this is believed to reside in that holes which had gone from the luminescent layer into the electron transport layer are recombined within the electron transport layer remote from the interface of the luminescent layer, disadvantageously resulting in luminescence of Alq3 within the electron transport layer (the same results as in non-patent document 1). On the other hand, in the light emitting device of Comparative Example 1, since the layer of TAZ functioned as a hole block layer, the luminescence of TAZ and the luminescence of Alq3 were prevented and, consequently, strong luminescence derived from the quantum dots was observed (the same results as in non-patent document 1).

In the light emitting device produced in Example 1, the luminescence efficiency was higher than that of the light emitting device produced in Comparative Example 1. The reason for this is that holes were introduced into the electron transport layer (BAlq2) constituting the light emitting device of Example 1 and could function as a recombination site. Further, the comparison of the results of the light emitting devices of Examples 2 to 4 shows that, when the thickness of the electron transport layer of BAlq2 is larger, the efficiency is higher because the recombination site is more biased toward the luminescent layer side within the electron transport layer and the produced excitons could efficiently migrate into the luminescent layer.

(Measurement of Hole Mobility)

In order to simply conduct relative evaluation of the hole mobility, the hole mobility of Alq3 and BAlq2 was indirectly relatively evaluated by the following method. A device for mobility measurement was prepared as follows.

A thin film of indium tin oxide (ITO) (thickness: 150 nm) was first formed by sputtering on a glass substrate to form an anode. The substrate with the anode formed thereon was cleaned and subjected to UV ozone treatment. Thereafter, a solution of polyethylenedioxythiophene-polystyrene sulfonic acid (abbreviated to “PEDOT-PSS”) was spin coated in the air onto the ITO thin film, and the coating was dried to form a hole injection layer (thickness: 20 nm). Next, a film of α-NPD and a film of Alq3 were formed in that order by a resistance heating-type vapor deposition method in vacuo (pressure: 5×10⁻⁵ Pa) to form a hole transport layer (thickness: 20 nm) and a measuring object layer (thickness: 100 nm) in that order. Further, a film of Au (thickness: 150 nm) was formed by a resistance heating-type vapor deposition method to form a cathode. Further, the assembly was sealed with an alkali-free glass in a glove box in a low-oxygen (oxygen concentration: not more than 0.1 ppm) and low-humidity (water vapor concentration: not more than 0.1 ppm) state to produce a device 1 for mobility measurement.

A device 2 for mobility measurement was produced in the same manner as described above, except that, instead of Alq3, BAlq2 was used as the measuring object layer.

It is considered that, when a voltage is applied to the devices 1 and 2 for mobility measurement, until the voltage increases to a value at which light is emitted, electrons do not flow and only holes flow. Further, the amount of current is greatly governed by the mobility of bulk rather than injection barrier at the interface under a high voltage. Accordingly, the amount of current under a high voltage reflects the hole mobility of the hole transport layer and the measuring object layer. In particular, when the hole mobility of the measuring object layer is lower than that of α-NPD (10⁻³ cm²/V/sec), the amount of current reflects the hole mobility of the measuring object layer having a larger thickness. For example, the comparison of current density at 10 V upon the application of voltage to the devices 1 and 2 for mobility measurement shows that the current density in the device 2 for mobility measurement is lower, and the hole mobility of BAlq2 is lower than that of Alq3.

1. A light emitting device comprising at least an anode, a hole transport luminescent layer formed of a material containing a hole transport material and quantum dots, an electron transport layer, and a cathode provided in that order, characterized in that
the hole mobility of the electron transport layer is smaller than that of tris(8-quinolinolato)aluminum complex (Alq3), and
in the hole transport luminescent layer, excitons generated in the electron transport layer migrate into the hole transport luminescent layer to cause luminescence.

2. The light emitting device according to claim 1, which meets [Ip(ETL)]<[Ip(HTL)+1.0 eV] wherein Ip(ETL) represents the absolute value of the ionization potential of an electron transport material that forms the electron transport layer; and Ip(HTL) represents the absolute value of the ionization potential of the hole transport material.

3. The light emitting device according to claim 1, wherein the electron transport layer has a hole mobility of not more than 10⁻⁷ cm²/V/sec.

4. The light emitting device according to claim 1, wherein the hole mobility is measured by providing a test piece formed of ITO (150 nm)/PEDOT (20 nm)/αNPD (20 nm)/measuring object (100 nm)/Au (100 nm), applying 10 V to the test piece, and, in this state, measuring a current value in a hole-only device.

5. The light emitting device according to claim 1, wherein the electron transport layer has a thickness of not less than 30 nm and not more than 150 nm.

6. The light emitting device according to claim 1, wherein the electron transport layer comprises BAlq2 as an electron transport material.

7. The light emitting device according to claim 1, wherein a dopant that enhances a recombination probability at sites on the hole transport luminescent layer side is contained at least at sites on the hole transport luminescent layer side of the electron transport layer.

8. The light emitting device according to claim 1, wherein the hole transport luminescent layer is any one of a layer comprising the hole transport material and the quantum dots dispersed in each other, a layer comprising a hole transport layer formed by phase separation between the hole transport material and the quantum dots and a monomolecular film of quantum dots, and a layer in a state intermediate between the layers.
